(19) United States
(12) Patent Application Publication
(10) Pub. No.: US 2016/0244265 A1
(43) Pub. Date: Aug. 25, 2016

(54) VIBRATING MACHINE

(71) Applicant: BÜHLER AG, Uzwil (CH)

(72) Inventors: Roberto MAGGIONI, Gorgonzola (IT); Kay HAUSCHULZ, Sankt Augustin (DE); Ralf KLIMKE, Altena (DE)

(21) Appl. No.: 15/027,507

(22) PCT Filed: Oct. 7, 2014
(86) PCT No.: PCT/EP2014/071389

§ 371 Date: Apr. 6, 2016

(30) Foreign Application Priority Data
Oct. 7, 2013 (IT) MI2013A001656

(51) Int. Cl. B65G 27/24; B06B 1/06; B65G 27/04; B06B 1/04; H02K 33/00; H01L 41/09

(52) U.S. Cl. CPC B65G 27/24; H02K 33/00; H01L 41/09; B65G 27/04; B06B 1/045; B06B 1/06

(57) ABSTRACT

A vibrating machine (1; 11) is described, in particular for machines for separating bulk foodstuffs, comprising the following features: a drive (3) suitable for generating vibrations at a frequency and with an amplitude, transmission members (4) suitable for transmitting the vibrations generated by the drive to an external element, and, in particular, an amplifier (5) suitable for amplifying the vibrations generated by the drive (3). The drive comprises an electromagnetic drive and/or a piezo actuator.

The present invention relates to a vibrating machine in particular for machines for separating bulk foodstuffs, in particular for separating machines for dried fruits, nuts and the like, and also to a method for vibrating by means of a vibrating machine.

Separating machines are currently necessary in foodstuff production and in particular in confectionery production, which machines, by gathering foodstuff pieces, such as dried fruits, nuts, kernels, sugar-coated candy, bonbons, and similar bulk material from an unordered pile, are able to arrange the individual foodstuff pieces in suitable positions.

The machines operate with lanes of small width in order to enable individual foodstuff pieces to be advanced forward. The advance of the foodstuff pieces in the lanes is additionally made possible by a slight inclination of the lanes and by the presence of a vibrating machine, which transmits vibrations to the lanes at suitable time intervals, such that it enables the dried fruits to be advanced forward in accordance with the gravity gradient.

The vibrating machines are therefore provided with systems for rapid connection and disconnection in order to enable a rapid transmission and non-transmission of the vibrations to the lane of the separating machine.

The above-mentioned prior art has some significant disadvantages.

Specifically, the vibrating machines and connection thereof to the lanes are very complex.

The complexity entails increased costs and requires regular maintenance, which increases the costs additionally.

The complexity additionally brings about an increased vulnerability of the machine. The vulnerability may lead to breaks in the vibrating machines and the machines connected thereto, which in turn may lead to problematic interruptions in production.

For example, a central eccentric drive can be provided, which can be coupled to individual vibrating channels via pneumatic switches.

Each vibrating channel may be driven either only via the common eccentric or not at all. Selective and individual control of the respective vibrating channels is not possible with this system.

Under consideration of this situation, the technical problem forming the basis of the present invention is that of inventing a vibrating machine, in particular for machines for separating foodstuff pieces, which vibrating machine is able to substantially counteract the above-mentioned disadvantages.

Within the scope of the technical problem, an important objective of the invention lies in obtaining a vibrating machine, in particular for machines for separating elements, which vibrating machine is simple and convenient.

A further important objective of the invention lies in inventing a vibrating machine, in particular for machines for separating elements, which vibrating machine is functionally robust and less susceptible to operational disruptions.

The technical problem and the specified objectives are achieved by a vibrating machine, in particular for machines for separating elements, as claimed in the accompanying independent claims.

The problem is solved in accordance with the invention by a vibrating machine, in particular for machines for separating bulk foodstuffs, which vibrating machine comprises a drive and transmission elements.

The drive is suitable for generating mechanical vibrations with a frequency and amplitude, in particular with respect to a support plane that is fixed in space.

The drive is driven in particular directly by means for generating electromagnetic waves, in particular means for generating electric fields. The vibrations are in particular in correlation with the electromagnetic wave or the electric field changes.

The transmission elements are in particular suitable for transmitting the vibrations generated by the drive to at least one external element, for example a component of a separating apparatus, such as a vibrating channel.

Each vibrating machine is preferably assigned an external element to be vibrated. Alternatively, a vibrating machine may also drive a plurality of external elements. These may be arranged in parallel or in series with respect to the vibrating machine. In accordance with the invention the drive is an electromechanical drive, preferably a linear electromechanical drive, in which an electromechanical converter converts electrical energy into motion. The converter preferably directly generates a linear motion back and forth, and the drive does not comprise an electric motor for a rotary motion.

In particular, the drive comprises an electromagnetic drive and/or the drive comprises a piezo element, in particular a piezo actuator.

Electromagnetic drives usually operate in accordance with the Lorentz principle. In accordance with this, a force is exerted onto a conductor through which current is passed and which is located in a magnetic field. It is irrelevant in the first instance whether the current is induced or fed. In order to generate the magnetic field, permanent magnets or electromagnets are used, which are created in turn by energizing a coil.

Piezo actuators use what is known as the reciprocal or inverse piezo ceramic effect, in accordance with which the change of an external electric field leads to a deformation of a piezo element, which consists of a piezo crystal or a piezo ceramic. By means of suitable kinematics, the change in shape can be converted into a desired form of motion, for example into a linear motion or a rotation. In the present case, a vibration is generated, preferably a linear motion back and forth.

The deformation of the piezo element can be transmitted directly or via a resonator to the transmission element.

Electromagnetic and piezoelectric drives can be produced relatively economically using small component parts. The electromagnetic and piezoelectric drives can be controlled individually without great outlay. A dedicated drive for each component to be vibrated can therefore be provided. The separation and the transport of the foodstuff pieces can thus be adjusted selectively and as necessary.

In an advantageous embodiment the vibrating machine comprises an amplifier, which is suitable for amplifying the vibrations generated by the drive.

In particular, the amplifier comprises at least one stationary element, at least one movable element, and means for generating potential, which means are suitable for repelling and attracting the stationary element and the movable element from/to one another.

The stationary element is preferably fixedly connected to a support plane fixed in space.

The movable element is preferably fixedly connected to the transmission elements.

The potential may generate a reset force and/or an amplification force, such that the vibration of the movable element generated by the drive is damped or amplified. An amplification preferably takes place, such that the amplitude of the vibration is increased.

The potential can be adjustable, such that more or less damping or amplification can be selected depending on the operating mode.

In an advantageous vibrating machine the amplifier comprises at least one stationary element and at least one movable element, wherein each stationary element is located beside a movable element, and vice versa. The vibrating machine preferably comprises a plurality of stationary elements and/or a plurality of movable elements, which are each arranged side by side in alternation.

In particular, the vibrating machine comprises an amplifier having two stationary elements and a movable element or an amplifier having two movable elements and a stationary element.

The amplifier is in particular embodied such that the means for generating potential comprise permanent magnets, which are arranged facing one another with reversed polarities.

The potential may thus act contactlessly on the stationary and movable elements. This is favorable in terms of energy, for example because no frictional force is effective.

The permanent magnets are preferably neodymium magnets.

Alternatively or additionally, the vibrating machine may have an amplifier comprising means for generating potential, which means comprise resilient elements which are suitable for mechanically connecting the stationary elements and the adjacent movable elements to one another.

The potential may in this way act field-free on the stationary and movable elements, such that there can be no superimpositions with the fields used with the drive.

The vibrating machine advantageously has an amplifier having a resonance frequency that is close to the frequency of the vibrations generated by the drive. This amplification is therefore implemented very quickly.

In an exemplary embodiment the vibrating machine comprises an electromechanical drive having a cylinder coil, a ferromagnetic element, and a permanent magnet.

The ferromagnetic element is arranged in the cylinder coil. Said element is suitable for magnetizing itself on account of an electric current present in the cylinder coil.

The ferromagnetic element or the permanent magnet form an oscillatable element. When the electric current in the cylinder coil changes, the ferromagnetic element or the permanent magnet perform a physical oscillation and thus generate vibrations.

The vibrations are preferably forwarded to the transmission element, from where they are forwarded, possibly via an amplifier, to a vibrating channel, which ensures that the foodstuff pieces lying in said vibrating channel are separated from one another.

The transmission elements advantageously consist of a transmission shaft, which is directly connected to the oscillatable element.

The movable elements of the amplifier can be arranged on the transmission shaft.

Alternatively, the stationary elements of the amplifier can also be arranged on the transmission elements, and the vibration is forwarded via the movable elements to the component to be vibrated, for example a vibrating channel.

The vibrating machine has a piezo actuator, and there is therefore usually no need for an amplifier. The changes in length of the piezo actuator induced by the changes of an electric field can be output directly to the transmission element and therefore transmitted to the component to be vibrated and to the bulk foodstuffs. The system does not require an amplifier, and a spring-loaded reset can be omitted.

If the operation of the piezo actuator is interrupted, the vibration is thus also immediately stopped and the channel is moved info a defined position.

The dynamics of the vibrating motion are freely adjustable via the motion curve of the piezo actuator.

Practically any motion curves can additionally be set within the scope of the possible amplitudes and frequencies using the piezo actuator. The inherent vibration of an amplifier does not need to be taken into consideration.

The vibration can thus be selected as required, where necessary so as to be gentle on the foodstuffs, and can be immediately interrupted if desired.

The piezo actuator is preferably designed to generate a vibration with a frequency of approximately 10-100 Hz, preferably approximately 50 Hz, and an amplitude, in particular a stroke, between 0.5 and 1.0 mm.

If the vibration is guided via suitable kinematics to the transmission element, in particular in a lever-like manner to a transmission shaft, strokes up to 1.5 mm can thus be generated, with which a sufficient force can also be transmitted to the component to be vibrated.

The problem is also solved by a separating machine for bulk foodstuffs, in particular dried fruits, which comprises a vibrating machine as described above.

In particular, the separating machine comprises a plurality of vibrating channels, wherein each vibrating channel is assigned a vibrating machine and can be set in vibration by said vibrating machine.

The problem is additionally solved by a method for vibrating bulk foodstuffs, in particular nuts, kernels, dried fruits, sugar-coated candy and bonbons, by means of a vibrating machine, in particular as described above.

In accordance with the invention vibrations at a frequency and with an amplitude are generated by a drive.

The vibrations are preferably generated relative to a support plane fixed in space.

The drive is in particular driven directly by means for generating electromagnetic waves.

In accordance with the invention transmission elements transmit the vibrations generated by the drive to at least one external element, preferably a vibrating channel.

The drive is an electromechanical drive, preferably a linear electromechanical drive, in particular an electromagnetic drive, or comprises a piezo element, in particular a piezo actuator.

The vibrations are preferably transmitted directly from the drive to an external element, in particular a vibrating channel, via the transmission element.

Here, in particular the motion sequence of the external element corresponds in particular to the motion sequence generated by a piezo actuator.

The external element therefore vibrates with the frequency and the motion profile predefined by the piezo actuator.

If the piezo actuator thus generates, for example, a sawtooth motion, a sine-wave-like motion or a square wave, the external element follows this dynamic without superimposition of an amplifier or resonator oscillation. If the piezo actuator stops its activity, the external element thus immediately comes to a standstill in a defined position.

Alternatively, the vibrations can be transmitted from the transmission element via an amplifier, in particular a spring-mounted amplifier, to at least one external element, in particular a vibrating channel.

Preferred embodiments are presented in the dependent claims.

The features and advantages of the invention will be explained hereinafter by the detailed description of a preferred embodiment of the invention with reference to the accompanying drawings.

In the drawings

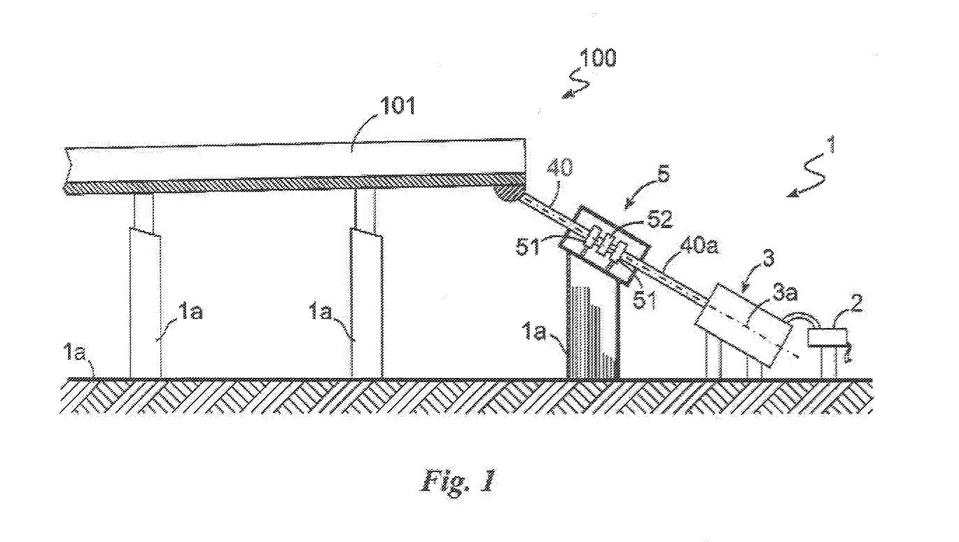

FIG. 1 shows a first schematic illustration of a first example of a vibrating machine according to the invention, which is connected to a machine for separating elements;

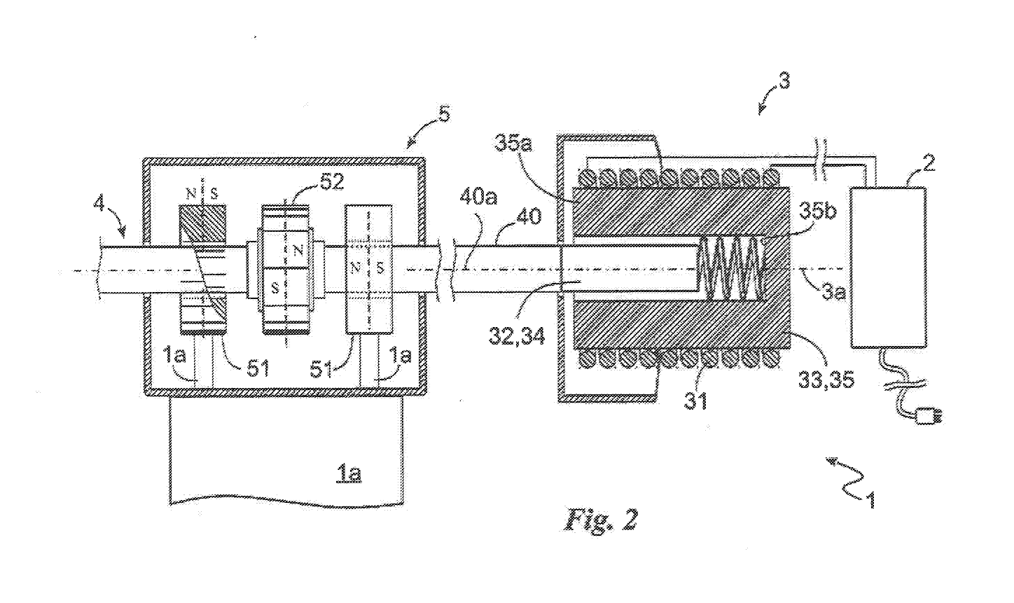

FIG. 2 shows the vibrating machine according to the invention according to FIG. 1 in cross section;

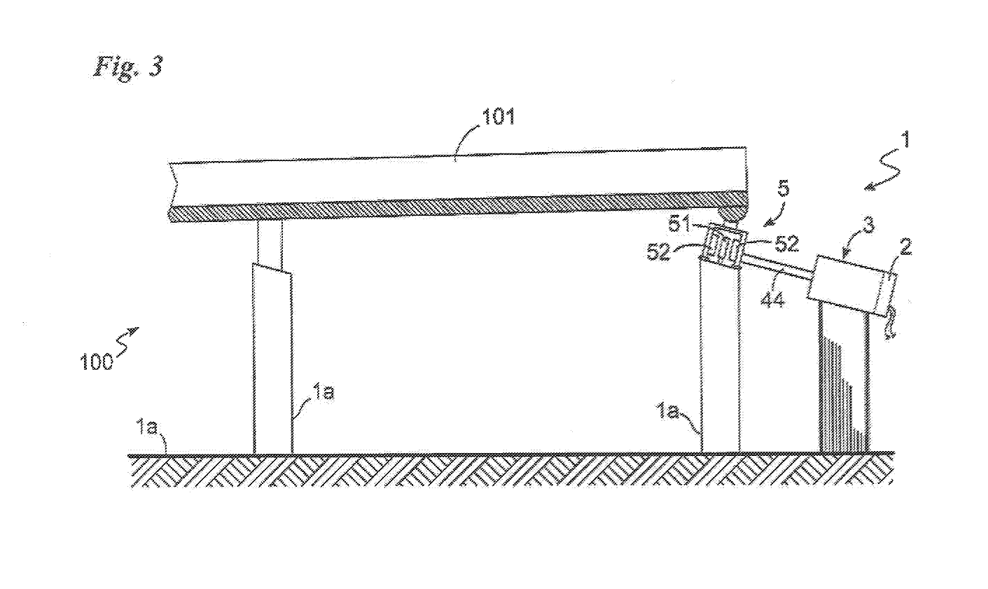

FIG. 3 shows a schematic illustration of a further example of a vibrating machine according to the invention, which is connected to a machine for separating elements;

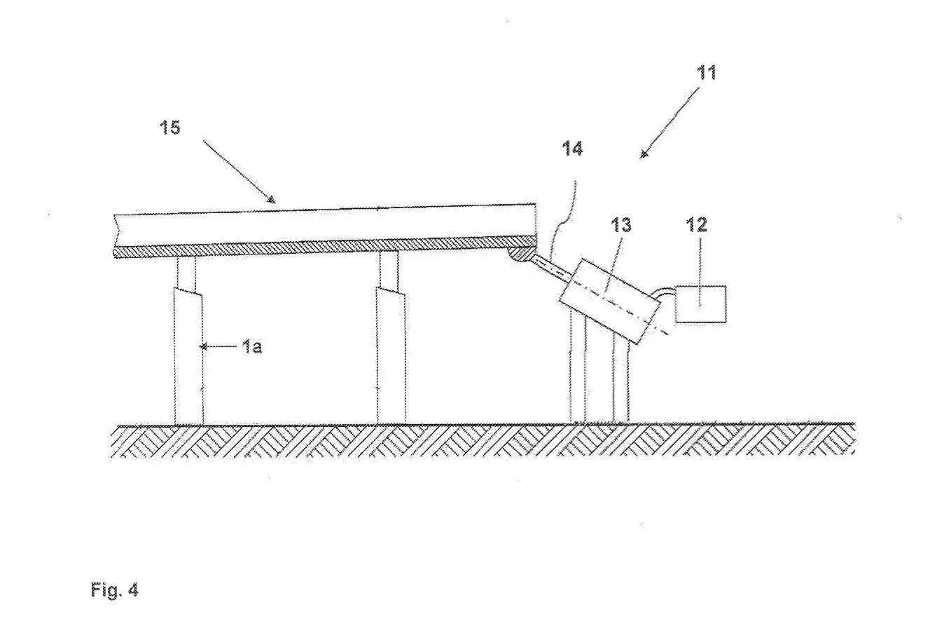

FIG. 4 shows a schematic illustration of a second example of a vibrating machine according to the invention, which is connected to a machine for separating elements;

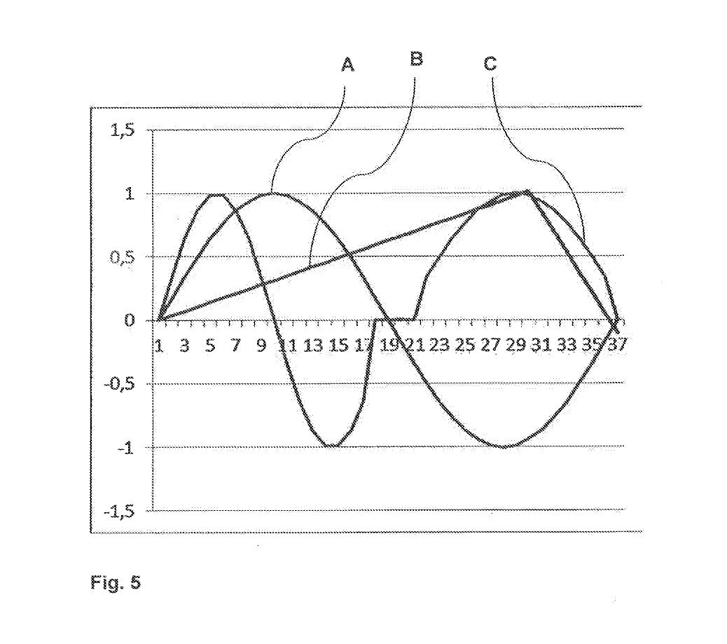

FIG. 5 shows examples of different motion curves.

The vibrating machine according to the invention is designated as a whole by the number 1 with reference to the above-mentioned figures.

The vibrating machine according to the invention is mounted in particular on machines for separating elements 100, more specifically on machines for separating dried fruits, for example for foodstuffs and in particular for confectionery.

The separating machines 100 described earlier generally comprise a plurality of lanes 101, which are suitable for forwarding elements in rows of approximately one element in each case. These lanes 101 are generally slightly inclined, and vibrations have to be transmitted to these lanes 101 in order to enable the elements to be advanced forward in the direction of the gravity gradient.

The vibrating machine 1 is arranged in a support plane 1a, i.e. of the ground or of an element fixedly connected thereto.

The vibrating machine 1 generally comprises means for generating an electromagnetic wave 2, an electromagnetic drive 3, which is suitable for generating vibrations in respect of the support plane 1a, an amplifier 5, which is suitable for amplifying the vibrations generated by the electromagnetic drive 3, and transmission members 4, which are suitable for transmitting the vibrations from the drive to the amplifier and to an external element, in particular to a remaining part of the machine 100, in particular to the lane 101.

More specifically, the means for generating the electromagnetic wave 2 are electronic means known per se, which are suitable for connection to the mains grid, to batteries, or something else and can generate a wave or an electromagnetic signal in a desired and possibly pre-set form and frequency. They are suitable in particular for generating a square wave with frequencies preferably between 0.5 s and 10 ms, more preferably between 100 ms and 50 ms, a voltage between 15 V and 30 V, preferably 24, and an amperage between 0.5 A and 2 A, preferably 1 A. It is even more preferable if the square wave oscillates between a positive phase between the specified voltages and frequencies and a zero phase; in addition, the positive phase preferably has a longer duration compared with the negative phase, and preferably is more than two times as long and even more preferably between two times and three times as long. Similar means are used for example in distorters of electronic musical instruments or in a wide range of different types of similar devices and can be produced easily by a person skilled in this art.

The generation means 2 are arranged in the support plane 1a and are electrically connected to the electromagnetic drive 3. In particular, the electromagnetic wave 2 is sent directly to the electromagnetic drive.

The electromagnetic drive 3 is secured to the support plane 1a and is suitable for generating vibrations, in respect of this support plane 1a, with a frequency and deflection correlated with the electromagnetic wave. The electromagnetic drive 3 converts the electromechanical waves substantially into mechanical vibrations.

The electromagnetic drive 3 comprises a cylinder coil 31, which is fittingly directly connected to the generation means 2, a ferromagnetic element 32 in the cylinder coil 31, which ferromagnetic element is suitable for magnetizing itself on account of the electric current provided in the cylinder coil 31, and a permanent magnet 33. In addition, one of the ferromagnetic element 32 and permanent magnet 33 is an oscillatable element 31 in respect of the support plane 1a. The oscillations are generated on account of the fluctuation of the electromagnetic properties of the ferromagnetic element 32, which are to be attributed to the fluctuation of the polarity or the intensity of the electric current in the cylinder coil 31, and which generates vibrations.

The vibrations preferably have the same frequency as the aforementioned electromagnetic waves and a deflection between 1 mm and 1 cm and even more preferably between 3 mm and 4 mm.

The oscillatable element 34 is preferably the ferromagnetic element and fittingly a prismatic or cylindrical or similar element, which is arranged concentrically on a stationary element 35, which is connected fixedly to the support plane 1a and which is formed fittingly by the permanent magnet 33. The stationary element 35 is preferably cylindrical or the like and is preferably an element having side wails 35a and just a base surface 35b, which is suitable for holding the oscillatable element.

In addition, a resilient element 36 is preferably positioned between the base surface 35b and the oscillatable element 34 and is suitable for responding to the movements caused by the electromagnetic forces.

The stationary element 35 is lastly surrounded fittingly by the cylinder coil 31, and the axis of the cylinder coil 3a coincides fittingly with the primary direction of extension of the oscillatable element 34 and preferably also with the indentation in the stationary element and therefore preferably with the direction of the oscillations of the oscillatable element.

The oscillatable element 34 is mechanically connected to the transmission members 4. They preferably comprise and/or consist of a transmission shaft 40, which is directly connected to the oscillatable element 34 and preferably has an axis 40a, which coincides with the axis of the cylinder coil 3a.

The amplifier 5, which is suitable for amplifying the vibrations generated by the electromagnetic drive 3, comprises at least one stationary element 51, which is fixedly connected to the support plane 1a, at least one movable element 52, which is fixedly connected to the transmission members 4 and is preferably fixedly connected to the shaft 40, and means 53 for generating potential, which are suitable for repelling and attracting the stationary element 51 and the movable element 52 from/to one another.

In addition, the amplifier 5 comprises a plurality of at least one stationary element 51 and movable element 52, in particular the amplifier 5 comprises two of a stationary element 51 and movable element 52 and a remaining element, which is stationary 51 or movable 52. Stationary elements 51 are additionally arranged fittingly beside movable elements, and vice versa. The stationary elements 51 and the movable elements 52 substantially alternate and in particular are three in number.

In FIG. 1 and in FIG. 2 two lateral stationery elements 51 and a middle movable element 52 are illustrated by way of example, said movable element being secured to the shaft 40; in FIG. 3, by contrast, two lateral movable elements 52 are illustrated, which are fixedly connected to a structure which is in turn fixedly connected to the shaft 40 and is secured to the support plane 1a via runners.

The means 53 for generating potential preferably comprise permanent magnets, which are arranged facing one another with reversed polarities (FIG. 2). They are preferably rare-earth magnets, preferably neodymium magnets, which are preferably annular, in addition have an axial N/S polarization and in addition preferably have an outer diameter between 1 cm and 5 cm and in addition have a magnetic force of attraction between 5 kgp and 15 kgp and more preferably between 7 kgp and 10 kgp. They are additionally preferably arranged at a distance from one another between 1 cm and 4 cm.

As an alternative, the means 53 for generating potential comprise resilient elements, which mechanically connect the stationary elements 51 and the movable elements 52 located therebeside.

In addition, the amplifier 5 has a resonance frequency close to the frequency of the vibrations generated by the electromagnetic drive 3 and therefore close to the vibrations transmitted by the drive 3, such that the mechanical vibrations of the drive 3 are considerably multiplied, in particular with a transmission factor, i.e. with a ratio between the output and input vibrations greater than 5 and preferably greater than 10.

As is known, the resonance frequencies are dependent on the physical properties of the system and can be easily selected by a person skilled in this art. The amplifier 5 may lastly be arranged substantially in the region of a support of the lane 101 (FIG. 3) or along the shaft 40 (FIG. 1).

The operating principle of the vibrating machine 1, which has been described above in terms of structure, is as follows. It also outlines a new innovative method.

The generation means 2, which may be connected to control means such as computers and the like and a power source, are easily regulated in terms of frequency, amplitude and form of the generated electromagnetic waves. They are additionally activated and deactivated with extreme promptness and speed.

The electromagnetic waves are converted by the electromagnetic drive 3 into mechanical waves, or better still vibrations, in the direction of the axis 3a, which coincides with the axis 40a of the shaft 40.

The waves are transmitted from the transmission members 4 to the amplifier 5. The movable elements 51 therefore vibrate at the same frequency in contrast to the means 53 for generating potential, which are secured to the stationary elements 52.

Thanks to the selected properties, for example those obtained by application of the described physical dimensions, the interaction between the stationary elements 52 and the movable elements 51 and the means 53 for generating potential amplify the vibrations in terms of deflection, in particular when the amplifier operates close to the resonance frequency and in particular when the means 53 are magnetic, such that substantially all abrasion and all damping caused by the abrasion are cancelled.

The transmission members 4 therefore transmit the vibrations to the external element, such as the lane or a similar element.

The separating machine 100 can therefore allow the elements contained there to advance or can stop said elements by simple and quick activation and deactivation of the generation means 2.

Significant advantages are attained with the invention.

Specifically, the vibrating machine 1 is simple and convenient. In particular, it does not comprise any complex mechanical parts, but only electrical means for activation and deactivation.

The costs for the finished separating machine are therefore approximately 40% of the costs of the known machines. A large part of the costs originated from the vibrating machines, which are to be mounted on each individual lane.

The machine is additionally very robust and un-susceptible to disruption, since various mechanical components simply are not provided.

The invention may have variants that fall within the scope of the inventive concept and within the scope of protection defined by the claims arid technical equivalents thereof.

FIG. 4 shows a schematic illustration of a second example of a vibrating machine 11 according to the invention which is connected to a machine for separating elements.

The vibrating machine 11 generally comprises means for generating an electric field 12, and a piezo actuator 13, which is suitable for generating vibrations in respect of the support plane 1a. The vibrations generated by the piezo actuator 13 are to be transmitted via a transmission element 14 to an external element, in particular to a component 15 to be vibrated, in particular to a vibrating channel.

By way of example, a Piezomove linear actuator from company PI can be used as piezo actuator 13, for example a P-602, which enables distances of travel up to 1 mm and forces up to 100 N.

The linear actuator has a housing made of stainless steel and therefore can be used without difficulty in the food industry. With dimensions of 12.6 cm×3.4 cm×1.4 cm, it allows a compact structure.

FIG. 5 shows examples of different motion curves that can be generated with the vibrating apparatus, wherein the physical deflection of the transmission element in mm is plotted over time.

Curve A corresponds to a sinusoidal oscillation, as can be generated with an electromechanical drive, as described above, or a piezo actuator.

Curves B and C are examples of selectively set motion curves, which do not correspond to inherent oscillation, for example of an amplifier, and can be transmitted directly from the piezo actuator to the transmission element and the component to be vibrated.

1-14. (canceled)

15. A vibrating machine comprising:
a drive,
wherein the drive is suitable for generating vibrations,
transmission elements,
and the drive is an electromechanical drive.

16. The vibrating machine as claimed in claim 15, wherein the drive is driven directly by means for generating electromagnetic waves.

17. The vibrating machine as claimed in claim 15, wherein the drive is an electromagnetic drive or comprises a piezo element.

18. The vibrating machine as claimed in claim 15, wherein the vibrating machine comprises an amplifier which is suitable for amplifying the vibrations generated by the drive.

19. The vibrating machine as claimed in claim 18, wherein the amplifier comprises a stationary element, which is fixedly connected to the support plane, at least one movable element, which is fixedly connected to the transmission elements, and means for generating potential, which means are suitable for repelling and attracting the stationary element and the movable element from/to one another.

20. The vibrating machine as claimed in claim 18, wherein the amplifier comprises a plurality of at least one of the stationary element and the movable element, and each stationary element is located beside movable elements, and vice versa.

21. The vibrating machine as claimed in claim 19, wherein the amplifier comprises two of one of the stationary element and the movable element and one of the remaining of the stationary element and the movable element.

22. The vibrating machine as claimed in claim 18, wherein the means for generating potential comprises permanent magnets which are arranged facing one another with reversed polarities.

23. The vibrating machine as claimed in claim 22, wherein the permanent magnets are neodymium magnets.

24. The vibrating machine as claimed in claim 18, wherein the means for generating potential comprises resilient elements, which are suitable for mechanically connecting the stationary elements and the adjacent movable elements to one another.

25. The vibrating machine as claimed in claim 18, wherein the amplifier has a resonance frequency, which is close to a frequency of the vibrations generated by the drive.

26. The vibrating machine as claimed in claim 15, wherein an electromechanical drive comprises a cylinder coil, a ferromagnetic element, which is located in the cylinder coil and is suitable for magnetizing itself on account of electric current present in the cylinder coil, and a permanent magnet, and one of the ferromagnetic element and the permanent magnet is an oscillatable element due to a change in the electric current in the cylinder coil and generates vibrations.

27. The vibrating machine as claimed in claim 28, wherein the transmission elements consist of a transmission shaft, which is directly connected to the oscillatable element, and are positioned on elements of an amplifier.

28. The vibrating machine as claimed in claim 27, wherein the transmission elements are positioned on stationary elements of an amplifier.

29. A separating machine for bulk foodstuffs, which comprises a vibrating machine as claimed in claim 15.

30. The separating machine as claimed in claim 29, wherein a respective vibrating machine is provided for each vibrating channel.

31. A method for vibrating bulk foodstuffs by a vibrating machine, wherein
vibrations in a frequency and amplitude are generated by a drive, and
transmission elements transmit the vibrations, generated by the drive, to at least one external element, and
the drive is an electromechanical drive.

32. The method as claimed in claim 31, wherein the bulk foodstuffs are dried fruits.

33. The method as claimed in claim 31, wherein the drive is driven directly by means for generating electromagnetic waves.

34. The method as claimed in claim 31, wherein the electromechanical drive is an electromagnetic drive or comprises a piezo element.

35. The method as claimed in claim 31, wherein the vibrations are transmitted from the drive via the transmission element directly to an external element.

36. The method as claimed in claim 35, wherein the external element is a vibrating channel.

37. The method as claimed in claim 31, wherein in the motion sequence of the external element corresponds to the motion sequence generated by the drive.

38. The method as claimed in claim 31, wherein the vibrations are transmitted from the transmission element via an amplifier to at least one external element.

39. The method as claimed in claim 38, wherein the amplifier is a spring-mounted amplifier.
